(19) United States
(12) Patent Application Publication
(10) Pub. No.: US 2016/0141286 A1
(43) Pub. Date: May 19, 2016

(54) Carrier For An Optoelectronic Semiconductor Chip And Optoelectronic Component

(71) Applicant: OSRAM OPTO SEMICONDUCTORS GMBH, Regensburg (DE)

(72) Inventors: Jurgen HOLZ, Wenzenbach (DE); Frank SINGER, Regenstauf (DE)

(21) Appl. No.: 14/889,771

(22) PCT Filed: May 21, 2014
(86) PCT No.: PCT/EP2014/060456

§ 371 Date: Nov. 6, 2015

(30) Foreign Application Priority Data
May 31, 2013 (DE) 10 2013 105 631.8

(51) Int. Cl. H01L 27/02; H01L 29/861; H01L 33/48; H01L 31/0203; H01L 23/00; H01L 31/0224; H01L 31/02; H01L 25/16; H01L 33/62

(52) U.S. Cl. CPC H01L 27/0255; H01L 25/167; H01L 29/8611; H01L 33/486; H01L 33/62; H01L 24/94; H01L 31/0224; H01L 31/02016; H01L 31/0203; H01L 2924/12036; H01L 2933/0016; H01L 2933/0066; H01L 2933/0033

(57) ABSTRACT

A carrier (1) for an optoelectronic semiconductor chip comprising: (2) base body (10), which comprises a first main surface (10a) and a second main surface (10b), at least one recess (11), which is introduced into the base body (10) and completely penetrates the base body (10) from the first main surface to the second main surface, and a filler material (12), which is introduced into the at least one recess (11). The base body (10) is formed using silicon of a first conductivity type. The filler material (12) is formed using polycrystalline silicon of a second conductivity type, the polarity of which differs in particular from the first conductivity type. The base body (10) and the filler material (12) are in direct contact with one another at points.

Document WO 2012/034752 describes a carrier for an optoelectronic semiconductor chip and an optoelectronic semiconductor component.

One object to be achieved is to specify a carrier and an optoelectronic semiconductor component, which are producible particularly cost-effectively.

According to at least one embodiment of the carrier, the carrier is suitable as a carrier for an optoelectronic semiconductor chip. The optoelectronic semiconductor chip can be, for example, a light-emitting diode chip, a laser diode chip, or a radiation-detecting chip, for example, a photodiode chip. The carrier is capable of mechanically supporting and carrying the optoelectronic semiconductor chip. Furthermore, the carrier is provided for the purpose of electrically contacting the optoelectronic semiconductor chip. The carrier can thus in particular be a terminal carrier or a printed circuit board, which can be connected to the optoelectronic semiconductor chip in a mechanically fixed and electrically conductive manner.

According to at least one embodiment of the carrier, the carrier comprises a base body. The base body has a first main surface and a second main surface. The first main surface is, for example, the top surface of the base body. The second main surface is then the bottom surface of the base body, which is opposite to the top surface of the base body. The base body is formed using an electrically conductive material, for example. The base body can be embodied as homogeneous in this case. That is to say, the base body is formed using a single material in this case and consists of this material except for possible contaminants and dopants.

According to at least one embodiment of the carrier, the carrier comprises at least one recess. The carrier can comprise two, three, or a plurality of similar recesses. The at least one recess of the carrier is introduced into the base body. The material of the base body is removed in the region of the recess of the carrier. The recess extends in the base body from the first main surface to the second main surface. In this case, the recess extends, for example, along a straight line between the first main surface and the second main surface, wherein the straight line can extend perpendicularly to the first and/or to the second main surface in the scope of the production tolerance.

The at least one recess penetrates the base body completely in this case. That is to say, the recess is, for example, a hole in the base body, which extends from the first main surface to the second main surface, and the material of the base body is completely removed in the region thereof. Alternatively, the region of the recess can already be kept free during the production of the base body, so that no removal of the material is necessary to form the recess.

According to at least one embodiment of the carrier, the carrier comprises a filler material, which is introduced into the at least one recess. The filler material preferably fills up the recess completely in the scope of the production tolerance. The filler material is different from the material of the base body.

The filler material is introduced into the recess of the base body. That is to say, during the production of the carrier, firstly a recess is provided or the recess is created, and subsequently the filler material is introduced into the recess. The region of the filler material of the base body is therefore not created by doping or oxidation of the material of the base body, but rather filler material is decanted into the recess of the base body.

According to at least one embodiment of the carrier, the base body is formed using silicon. It is possible in this case that the base body consists of silicon. The base body is formed using crystalline silicon in particular. The base body has silicon of a first conductivity type in this case. That is to say, the silicon of the base body is, for example, p-doped or n-doped. The base body is formed as electrically conductive in this manner. The silicon of the base body can be p-doped using boron, for example.

According to at least one embodiment of the carrier, the filler material is formed using polycrystalline silicon of a second conductivity type. In this case, the filler material can consist of the polycrystalline silicon or the filler material can comprise a further material, for example, a metal, in addition to the polycrystalline silicon. The polycrystalline silicon consists of small silicon crystals and thus differs from monocrystalline silicon, using which the base body is formed, for example. However, crystalline regions which each adjoin one another are present in the polycrystalline silicon.

The polycrystalline silicon has a second conductivity type, which is preferably different from the first conductivity type. For example, the polycrystalline silicon can be n-doped or p-doped. That is to say, the first and the second conductivity type differ from one another in particular by way of the polarity thereof.

The filler material can be formed as electrically conductive in this manner. For example, the polycrystalline silicon is doped using phosphorus and has a specific resistance of at most 35 ohm cm, in particular at least 20 ohm cm.

According to at least one embodiment of the carrier, the base body and the filler material are in direct contact with one another at points. That is to say, there are regions between base body and filler material, in which the base body and the filler material directly adjoin one another and have a common intersecting surface. In these regions, an electrically conductive connection then also exists between the base body and the filler material. In this case, a thin layer made of a silicon oxide can be arranged between the filler material and the material of the base body, which is created, for example, after the creation of the recess in the base body by oxidation of the base body. The thin layer made of silicon oxide has, for example, a thickness of at most 5 nm, for example, of 3 nm. The thin layer made of silicon oxide is helpful, for example, if the polycrystalline silicon of the filler is to be deposited on the silicon of the base body, since it suppresses epitactic and therefore crystalline growth of the deposited silicon in the recess.

According to at least one embodiment of the carrier for an optoelectronic semiconductor chip, the carrier comprises a base body, which has a first main surface and a second main surface, at least one recess, which is introduced into the base body and completely penetrates the base body from the first main surface to the second main surface, and a filler material, which is introduced into the at least one recess. In this case, the base body is formed using silicon of a first conductivity type and the filler material is formed using polycrystalline silicon of a second conductivity type. The base body and the filler material are in direct contact with one another at points.

By way of the use of silicon both for the base body and also for the filler material in the recesses, a carrier is specified which is producible particularly cost-effectively. The filler material forms through-contacts (vias) in the carrier in this case, which extend through the base body. Because fewer metals than typical or no metal, but rather polycrystalline silicon is used as the filler material, these through-contacts can be created particularly cost-effectively. Furthermore, the base body and the filler material have similar coefficients of thermal expansion because of the similar materials used, which increases the cycle stability of the carrier in use as a carrier for an optoelectronic semiconductor chip. Furthermore, the polycrystalline silicon adheres very well to the silicon of the base body, so that no mechanical problems result, for example, a delamination of the filler material from the recesses of the base body.

According to at least one embodiment of the carrier, a space charge zone is formed in the region of the direct contact between the base body and the diffusion of the filler material. That is to say, in the region of the direct contact, a depletion zone or barrier layer arises and therefore a region in which space charges having excess and deficiency of charge carriers are opposite to one another. In this manner, the region of the direct contact between the base body and the filler material appears to be charge neutral. This is achieved in that base body and filler material have unlike conductivity types to one another. For example, the filler material is n-conductive and the base body is p-conductive. In this manner, a pn-junction also forms in the region of the direct contact between the filler material and the base body.

Because of the space charge zone and the formed pn-junction, electrical insulation between the base body and the filler material can be omitted at least at points along the recess. For example, the base body and the filler material can directly adjoin one another along the entire recess. Nonetheless, the base body and the filler material can be used for the connection to p-terminal and n-terminal regions of an optoelectronic semiconductor chip, without a short-circuit occurring. In addition, the advantage results that the carrier, in particular the pn-junction of the carrier, acts as an ESD (electrostatic discharge) protection of the optoelectronic semiconductor chip if it is connected in antiparallel to a pn-junction of the optoelectronic semiconductor chip. For this purpose, the n-conductive region of the carrier, i.e., for example, the filler material, is connected in an electrically conductive manner to the p-terminal region of the optoelectronic semiconductor chip, and the p-conductive region of the carrier, i.e., for example, the base body, is connected in an electrically conductive manner to the n-conductive terminal region of the optoelectronic semiconductor chip.

The carrier described here therefore has, in addition to its properties for the mechanical carrying of the optoelectronic semiconductor chip and for the electrical contacting of the optoelectronic semiconductor chip, the further function of an ESD protection for the optoelectronic semiconductor chip. The carrier is based on the finding in this case, inter alia, that optoelectronic semiconductor chips frequently have no or only inadequate ESD protection. Therefore, also in dependence on the size of the optoelectronic semiconductor chip, an ESD protective diode or another ESD protection, for example, a varistor, has to be installed in addition to the optoelectronic semiconductor chip in an optoelectronic semiconductor component. This increases the costs and the size of corresponding optoelectronic semiconductor components.

Using the present carrier, an ESD protective diode can be integrated cost-effectively in the region of the recesses in the carrier, so that further ESD protection measures are not necessary. The component produced in this manner can then be further processed and can be used, for example, as a surface-mountable device. No further housing is necessary to integrate an ESD protection into the component. The pn-junction used as the ESD protection in the carrier can already be integrated particularly simply and cost-effectively at the wafer level because of the materials used. That is to say, the recesses can be created, for example, in a commercially available 6-inch, 8-inch, or 12-inch silicon wafer and filled with the filler material at the wafer level. In this manner, it is possible to produce a plurality of the carriers in the composite.

According to at least one embodiment of the carrier, a first electrically insulating material is arranged at points in the at least one recess, preferably in each recess, between the filler material and the base body. The electrically insulating material can be, for example, a silicon dioxide or a silicon nitride, which adheres particularly well on the base body and on the filler material. In this embodiment, the region in which a space charge zone is formed is reduced in size, since the region of the direct contact between base body and filler material is reduced in size. Due to the use of an electrically insulating material in the recess to reduce in size the region of the direct contact between base body and filler material, the electrical properties of the pn-junction, which forms between base body and filler material, can thus be set. Furthermore, the cross-sectional area of the filler material is settable in a plane parallel to the first and/or second main surface of the base body and is reduced, for example.

According to at least one embodiment of the carrier, the filler material comprises a metal, wherein the polycrystalline silicon is arranged at least at points between the metal and the base body. In this case, the filler material does not consist of the polycrystalline silicon, but rather the filler material comprises at least one further material, namely a metal, for example, tungsten, aluminum, or titanium. Furthermore, it is possible that the filler material comprises a combination of at least two of these metals. The filler material then comprises, for example, the polycrystalline silicon, which is in direct contact at points with the base body.

The polycrystalline silicon can form a jacket surface, for example, which encloses the metal. The metal is arranged in this case like a metallic through-contact inside the through-contact made of polycrystalline silicon. The polycrystalline silicon is used to form a space charge zone and therefore to form an ESD protective diode inside the carrier. The electrical resistance of the through-contact is reduced by the metal, so that it can be formed having a smaller cross-sectional area, for example, than is necessary if the filler material consists of polycrystalline silicon.

The polycrystalline silicon is only introduced as a layer into the recess, which does not completely fill up the recess, for example, during the production of the carrier. A smaller recess remains, which completely penetrates the base body from the first to the second main surface and can subsequently be filled using the metal. The metal can be introduced, for example, via a CMP method, sputtering, or an alternating deposition-etching step into the recess, which is reduced in size by the polycrystalline silicon.

According to at least one embodiment of the carrier, a second electrically insulating material, which completely encloses the openings of the recess on the first main surface and/or the second main surface, is applied to the first main surface and/or the second main surface of the base body. The second electrically insulating material can thus be applied in a structured manner to at least one of the main surfaces of the base body. It is used to electrically insulate electrically unlike terminal regions of the carrier from one another. The second electrically insulating material can be formed using materials, for example, silicon dioxide or silicon nitride, which adhere particularly well on the base body. Furthermore, it is possible that the first electrically insulating material and the second electrically insulating material are formed using the same material and are applied onto the base body or introduced into the base body, respectively, in the same production step.

According to at least one embodiment of the carrier, a first cross-sectional area of the filler material on the first main surface and/or the second main surface is smaller than a second cross-sectional area inside the base body, which is arranged between the first main surface and/or the second main surface. The two cross-sectional areas extend in parallel to the first and/or to the second main surface in this case, for example. In other words, the filler material can have a larger cross section inside the carrier than where it is exposed on the upper or lower side of the base body, respectively. By way of the increased cross section inside the base body, the electrical resistance of the filler material and therefore the through-contact can be reduced. By way of the reduction in size of the cross-sectional area on the upper side and the lower side of the base body, the cross-sectional area can be adapted to the size of the terminal regions, for example, of the optoelectronic semiconductor chip, which is to be mounted on the carrier.

For example, the maximum cross-sectional area is at least 10,000 μm², for example, 225,000 μm². The thickness of the filler material is, for example, at least 100 μm, for example, 150 μm. With a specific resistance of the filler material of 0.001 Ωcm, a cross-sectional area of 225,000 μm², and a thickness of the filler material of 150 μm, for example, a resistance of approximately 0.07Ω results.

According to at least one embodiment of the carrier, an electrically conductive material is applied in a structured manner to the first main surface and/or the second main surface, which electrically conductive material is in direct contact with the filler material in a first region of the carrier and is in direct contact with the base body in a second region of the carrier. In this case, the electrically conductive material in the first region is electrically insulated from the electrically conductive material in the second region by the second electrically insulating material.

The electrically conductive material can be, for example, a metal, such as aluminum, copper, silver, gold, or an alloy having at least one of these materials. The electrically conductive material is used to connect the carrier on its lower side, for example, at the usage location. On the upper side of the carrier, i.e., on the side of the first main surface of the base body, the material is used for the connection to the optoelectronic semiconductor chip.

According to at least one embodiment of the carrier, a doped region, which comprises the first conductivity type, is arranged in the base body directly below the electrically conductive material in the second region on the first main surface and/or directly above the electrically conductive material in the second region on the second main surface. In this region, for example, additional doping of the base body can take place, to intentionally increase the conductivity of the base body in this region.

Furthermore, an optoelectronic semiconductor component is specified. The optoelectronic semiconductor component has a carrier described here. That is to say, all features disclosed for the carrier are also disclosed for the optoelectronic semiconductor component. Furthermore, the optoelectronic semiconductor component has an optoelectronic semiconductor chip, which comprises a first electrical terminal region and a second electrical terminal region. The optoelectronic semiconductor component can also have a plurality of optoelectronic semiconductor chips in this case, which each have first and second electrical terminal regions.

The optoelectronic semiconductor chip is arranged on the side facing toward the first main surface of the base body, i.e., the upper side, of the carrier, and the optoelectronic semiconductor chip is connected in an electrically conductive manner to the carrier via the first electrical terminal region and the second electrical terminal region.

The optoelectronic semiconductor chip is, for example, a large semiconductor chip, which has edge lengths of 350 μm or greater. In particular for such large optoelectronic semiconductor chips, the additional ESD protection, which the carrier described here can provide, has proven to be particularly advantageous. It has been shown in this case that such large optoelectronic semiconductor chips have less inherent ESD protection than is the case for smaller optoelectronic semiconductor chips. However, because of the higher current carrying capacity and the improved linearity of the light density thereof in dependence on the operating current, large optoelectronic semiconductor chips have advantages, in particular if the optoelectronic semiconductor chips are thin-film chips, in which a growth substrate is removed from the epitactically grown layers.

According to at least one embodiment of the optoelectronic semiconductor component, the first electrical terminal region of the semiconductor chip is connected in an electrically conductive and mechanical manner to the electrically conductive material in the first region of the carrier and the second electrical terminal region of the semiconductor chip is connected in an electrically conductive and mechanical manner to the electrically conductive material in the second region of the carrier, wherein the first electrical terminal region and the second electrical terminal region are each connected to an electrically unlike region of the carrier. The optoelectronic semiconductor chip has a pn-junction in this case, which is connected in antiparallel to the pn-junction of the carrier because of the connection of unlike terminal points of carrier and optoelectronic semiconductor chip.

In this manner, the carrier can form an ESD protection for the optoelectronic semiconductor chip. The optoelectronic semiconductor component can therefore be mounted, without further ESD protection measures, as a surface-mountable device, for example. The external terminal points of the optoelectronic semiconductor component are formed by the electrically conductive material on the lower side of the carrier, facing away from the semiconductor chip, which electrically conductive material is in direct contact with the filler material or the base body and is electrically insulated from one another via the second electrically insulating material.

Furthermore, a method for producing an optoelectronic semiconductor component described here is specified. All features described for the carrier described here and all features described for the optoelectronic semiconductor component described here are also disclosed for the method and vice versa.

In the method, firstly a plurality of carriers as described here are produced in the composite. For this purpose, the recesses are introduced into the material of the base body, which is provided as a disk, and filled using the filler material. The base body is provided in this case, for example, as a silicon wafer, for example, as a 6-inch, 8-inch, or 12-inch silicon wafer.

In a next method step, a plurality of optoelectronic semiconductor chips is applied to the plurality of carriers and connected in an electrically conductive manner to the carriers, wherein the optoelectronic semiconductor chips can be applied individually or also in the composite to the plurality of carriers. For example, the optoelectronic semiconductor chips can still be provided in the wafer composite. That is to say, the optoelectronic semiconductor chips are connected to one another via a growth substrate, for example, and are not yet isolated into individual optoelectronic semiconductor chips upon the application to the carriers. After the application of the optoelectronic semiconductor chips to the carriers, detachment of the growth substrate and isolation into individual optoelectronic semiconductor chips can then be performed, for example.

Finally, an isolation of the arrangement made of carriers and optoelectronic semiconductor chips to form individual optoelectronic semiconductor components is performed, wherein each optoelectronic semiconductor component comprises at least one optoelectronic semiconductor chip. During the isolation of the arrangement, the composite of carriers is then severed by sawing, cutting, or fracturing.

The carrier described here for an optoelectronic semiconductor chip, the optoelectronic semiconductor component described here, and the method described here for producing an optoelectronic component will be explained in greater detail hereafter on the basis of exemplary embodiments and the associated figures.

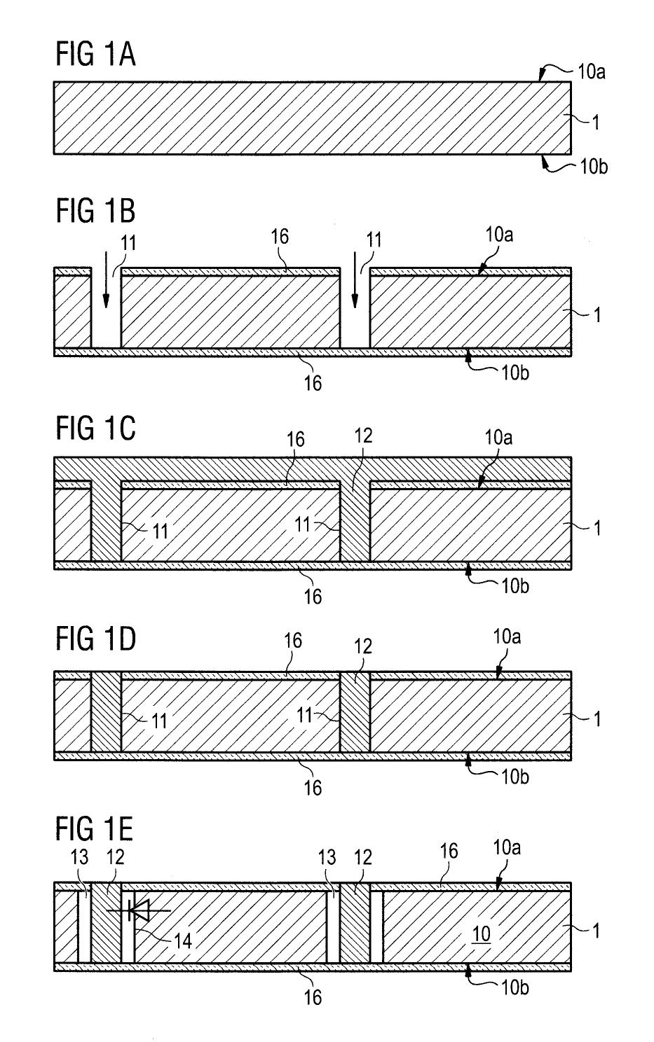

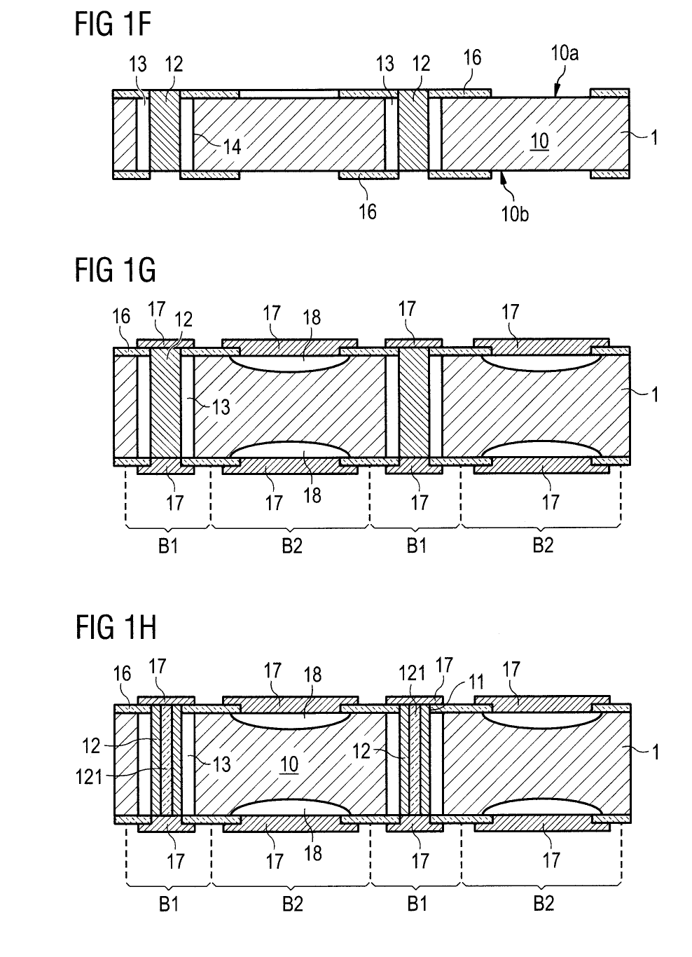

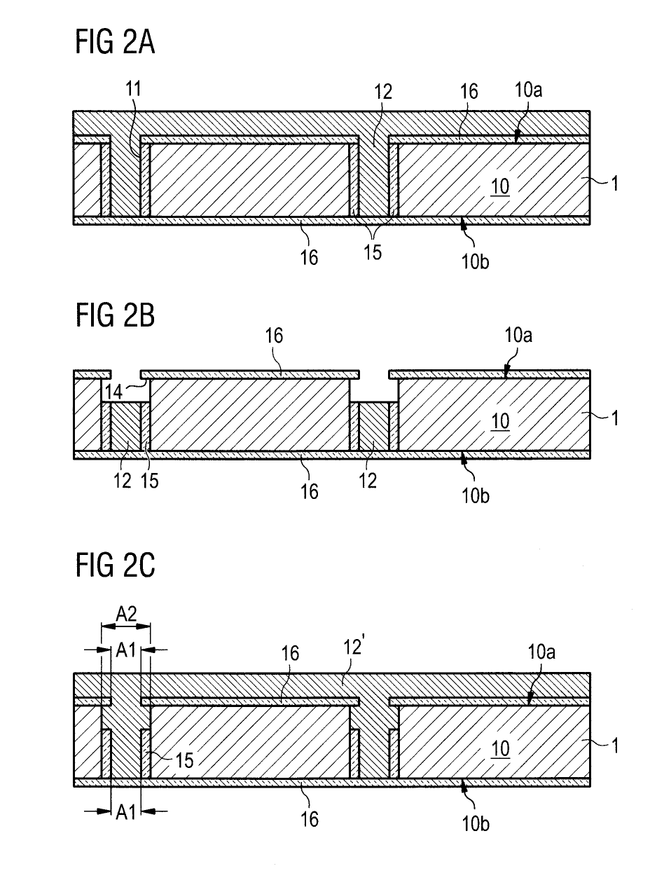

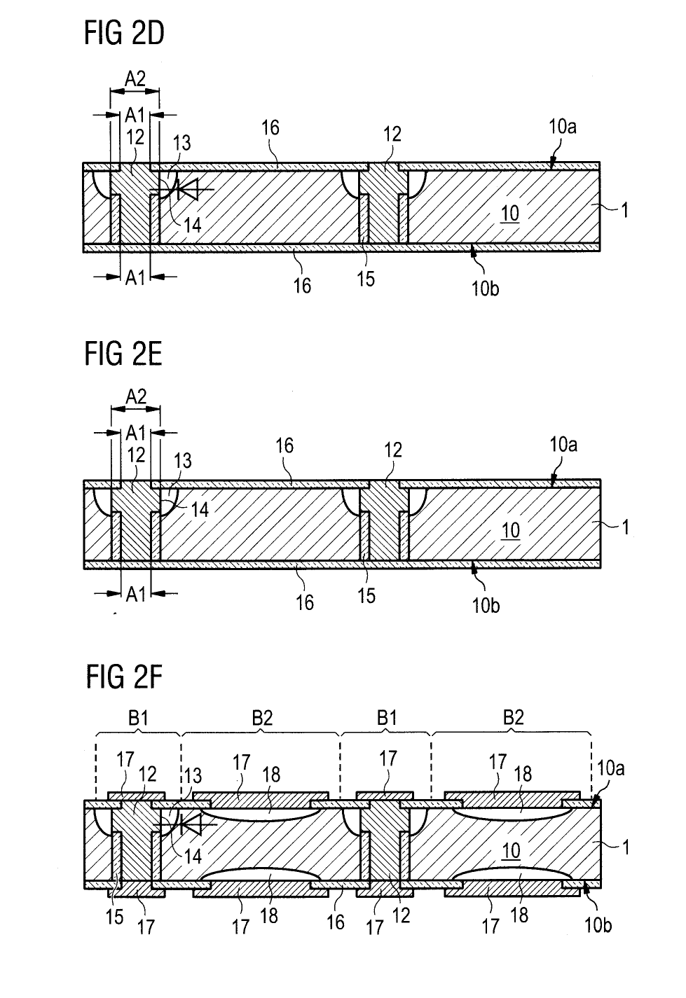

Partial steps of exemplary embodiments for producing optoelectronic semiconductor components described here and exemplary embodiments of carriers described here are explained in greater detail on the basis of FIGS. 1A to 1H and 2A to 2F.

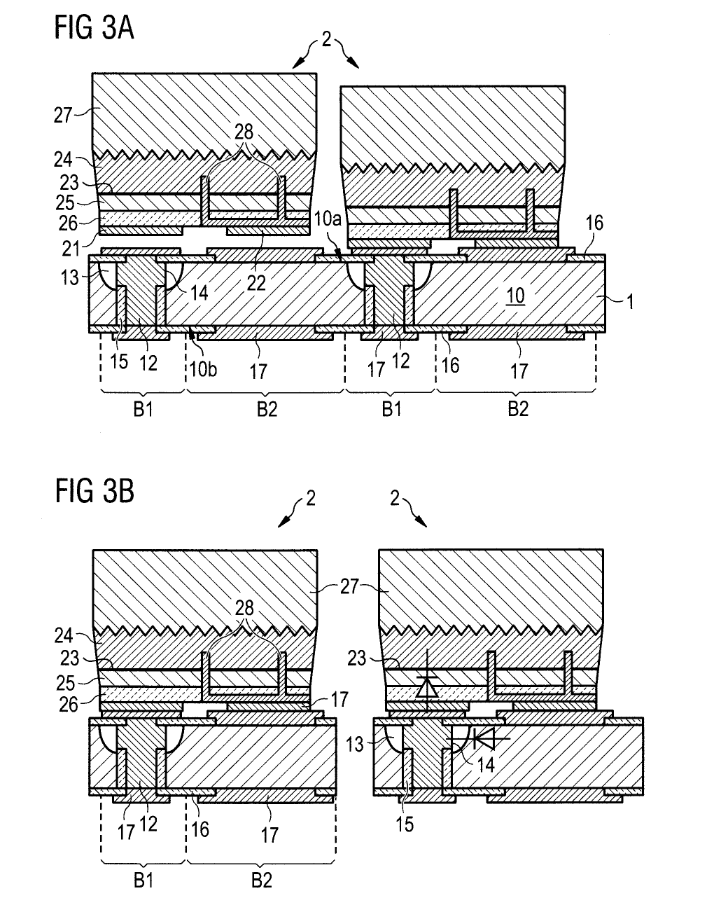

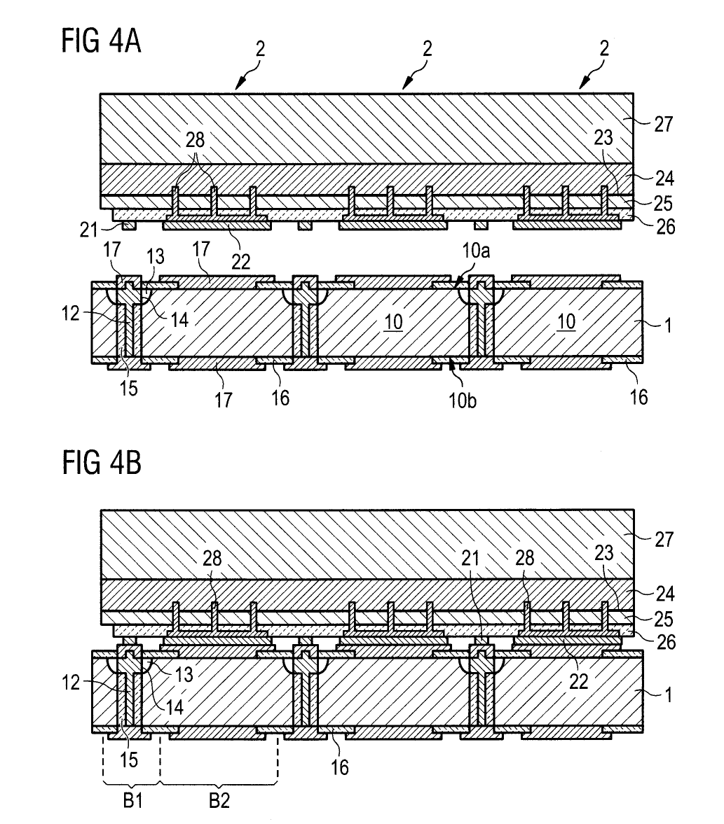

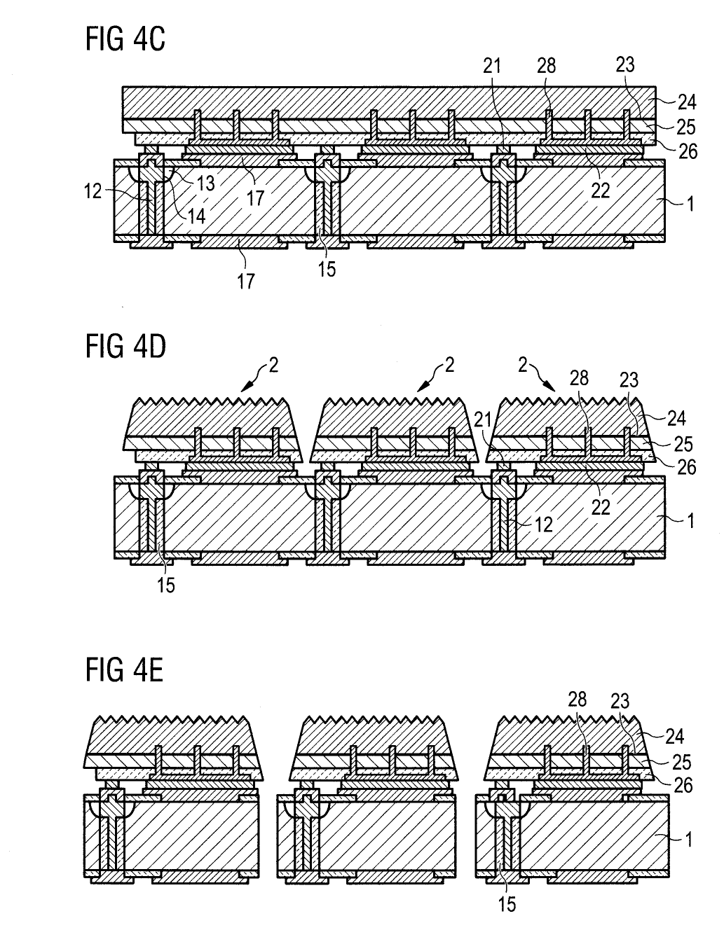

Exemplary embodiments of methods for producing optoelectronic semiconductor components described here and optoelectronic semiconductor components described here are explained in greater detail on the basis of FIGS. 3A, 3B and 4A to 4E.

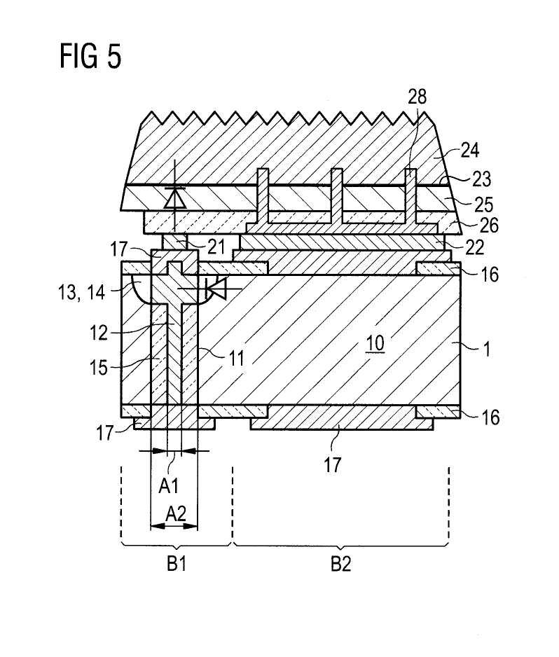

An optoelectronic semiconductor component described here is explained in greater detail on the basis of FIG. 5.

In the figures, identical or identically acting parts can each be provided with the same reference signs. The illustrated parts and the size relationships among one another are not to scale. Rather, individual parts, such as layers, structures, components, and regions can be shown exaggeratedly thick or large-dimensioned for better illustration ability and/or for better comprehension.

Partial steps of a method described here for producing an optoelectronic semiconductor component and a carrier described here are explained in greater detail on the basis of the schematic sectional illustrations of FIGS. 1A to 1G.

In a first method step, FIG. 1A, a base body 10 is provided, which can be a silicon monocrystalline wafer, for example. The base body 10 is p-conductive doped, for example. The base body comprises a first main surface 10a on the upper side and a second main surface 10b on the lower side. The base body 10 is formed, for example, by silicon doped with boron. The dopant concentration is at least 10¹⁹/cm² in this case.

In the next method step, FIG. 1B, the second electrically insulating material 16 is applied in a structured manner to the first main surface 10a and to the second main surface 10b. The second electrically insulating material 16 is a dielectric material, which is used as an etching mask and remains in the carrier in the proceedings. For example, the second electrically insulating material can be silicon dioxide or silicon nitride. The production of recesses 11 is performed in an anisotropic manner through the mask, which is formed using the second electrically insulating material 16, in the base body 10, via reactive ionic etching, for example. The recesses 11 penetrate the base body 10 from the first main surface 10a to the second main surface 10b in this case.

In the next method step, FIG. 1C, the recesses 11 are filled, in particular completely, using the filler material 12. The filler material 12 can also firstly be arranged on the upper side of the second electrically insulating material 16, facing away from the base body in this case. The filler material 12 is polycrystalline silicon, which can be n-doped using phosphorus, for example.

A CVD from the gas phase having in situ doping of the filler is suitable, for example, for introducing the polycrystalline silicon into the recesses 11. For example, pyrolysis of SiH₄ (silane) in a PVCD method and doping using PH3, BH3, B2H6, or AsH3 are performed. Alternatively, methods such as MBE or LPE can be used. Activation of the dopant can be performed by heating, for example, to temperatures of greater than 900° C. for minutes or longer. During the introduction of the filler, amorphous silicon can also be deposited, which becomes polycrystalline silicon by way of a following tempering step, for example, during the activation of the dopant.

Subsequently, FIG. 1D, the filler material 12 is removed in a dry chemical or wet chemical manner, for example, by back etching, from the upper side of the second electrical insulating material 16 facing away from the base body 10. Subsequently, a diffusion of charge carriers between the base body 10 and the filler material 12 is performed by tempering, for example, so that space charge zones 13 and a pn-junction 14 form. The tempering can be performed, for example, for at least 10 minutes at at least 900° C.

It is shown on the basis of FIG. 1F that in a next method step, the second electrically insulating material 16 is removed at points, so that the second electrically insulating material 16 completely encloses the filler material 12 on the first main surface 10a and the second main surface 10b and regions on the first main surface 10a and the second main surface 10b of the base body are exposed.

In the next method step, further p-doping, for example, using boron, of the base body 10 can be performed by, for example, planar implantation or diffusion in the exposed regions of the base body 10. In this case, dopant is introduced in such a concentration that no un-doping takes place in the filler material 12.

In the next method step, an electrically conductive material 17, for example, a metal, is applied in the first regions B1 of the carrier, which is located in direct contact with the filler material 12. In the second regions B2 of the carrier, the electrically conductive material 17 is applied such that it is located in direct contact with the base body 10. In this manner, terminal points of the carrier 1 are formed by the electrically conductive material.

An alternative exemplary embodiment of a carrier described here is described in greater detail in conjunction with FIG. 1H. In this exemplary embodiment, the recesses 11 are not completely filled using polycrystalline silicon as the filler material 12, but rather the filler material 12 comprises a metal 121 as a further filler material. The metal 121 is arranged in the recess 11, for example, such that the polycrystalline silicon is arranged between the metal 121 and the base body 10.

To produce such a carrier 1, the recess 11 is firstly created by etching and filled with polycrystalline silicon, for example, wherein the recess 11 is not completely filled with the polycrystalline silicon, for example, but rather the base body 10 is coated with the polycrystalline silicon in the region of the recess 11, without completely closing the hole in the base body. Alternatively, the recess 11 can be completely filled with polycrystalline silicon and it can be removed again at points in the center of the recess, for example, by etching.

The remaining part of the recess 11 is filled using the metal 121. The metal can be at least one of the following metals, for example: W, Al, Ti. For example, the metal 121 can comprise titanium in each case, which reacts with silicon to form TiSi, which is distinguished by a low ohmic contact resistance. The titanium can be introduced by sputtering, for example. Annealing is subsequently carried out at at least 600° C., for example. In a next step, after the removal of the titanium from the electrically insulating material 16, a second annealing step can be performed at a higher temperature, to create the TiSi, which has good conductivity.

Furthermore, it is possible that the metal 121 comprises titanium in combination with tungsten and/or aluminum. The titanium can prevent the formation of undesired compounds between tungsten and silicon or aluminum and silicon in this case, for example.

Overall, a through-contact results in this manner which has a jacket surface, which is formed using polycrystalline silicon, which encloses a metal core, which is formed using the metal 121. A through-contact results which forms an ESD protective diode with the material of the base body 10 and at the same time is distinguished by a low ohmic resistance. The space charge zone 13 is preferably formed in this case before the introduction of the metal 121.

Partial steps of a further exemplary embodiment of a method described here and an exemplary embodiment of a carrier described here are explained in greater detail in conjunction with FIGS. 2A to 2F.

In contrast to the method which is described in conjunction with FIGS. 1A to 1H, in this method, the inner sides of the recesses 11 are covered using the first electrically insulating material 15. The first electrically insulating material 15 can be a silicon nitride or a silicon oxide, for example. Furthermore, it is possible that the first electrically insulating material and the second electrically insulating material are formed integrally with one another and are applied in the same method step.

The recesses 11 coated in this manner using the first electrically insulating material 15 are filled using the filler material 12, see FIG. 2A.

In the next step, FIG. 2B, back etching of the filler material is performed into the recesses 11, such that a part of the first electrically insulating material 15 is removed inside the recess 11. For this purpose, for example, silicon dioxide is used for the first electrically insulating material 15 and silicon nitride is used for the second electrically insulating material 16 or first electrically insulating material 15 and second electrically insulating material 16 are formed using the same material, wherein the second electrically insulating material 16 is formed thicker than the first electrically insulating material 15. In both ways, it can be achieved that the first electrically insulating material 15 is completely removed at points in the recess 11 and the second electrically insulating material 16 remains on the first main surface 10a of the base body 10 during the dry chemical or wet chemical back etching.

In the next method step, FIG. 2C, filler material 12′ is deposited once again, which can also be doped polycrystalline silicon.

In the next method step, see FIG. 2D, diffusion of the dopant of the filler material 12 is performed by tempering, for example, again at a temperature of at least 900° C. over a time span of at least 10 minutes. Furthermore, etching away of the further filler material 12′ is performed such that the upper side of the second electrically insulating material 16 facing away from the base body 10 is exposed.

The space charge zone 13 and the pn-junction 14 result.

In the carrier 1 produced in this manner, the filler material 12 has a larger cross-sectional area A2 in the interior of the base body 10 than the smaller cross-sectional area A1 on the upper side and the lower side of the carrier 1. In this manner, the resistance of the through-contact, which is formed using the filler material 12, can be reduced, without the terminal surfaces on the upper side for connecting an optoelectronic semiconductor chip or on the lower side for connecting the carrier 1 at the intended location being enlarged.

As indicated in FIG. 2E, grinding down of the carrier 1 can optionally also be performed from the side of the second main surface 10a of the base body 10, wherein a distance from the carrier lower side to the pn-junction 14 of greater than 200 nm is advantageous.

If grinding down of the carrier 1 is performed, subsequently the second electrically insulating material 16 is once again applied and structured on the lower side. Thereafter, the method steps described in conjunction with FIG. 1G of the optional additional doping to form the doped region 18 and the application of the electrically conductive material 17 to form the contact points of the carrier 1 are performed. The carrier 1 shown in FIG. 2F results.

In conjunction with FIGS. 3A and 3B, an exemplary embodiment for producing an optoelectronic semiconductor component described here is explained in greater detail. In this exemplary embodiment, firstly a carrier 1 is provided, as is produced, for example, by one of the methods described in conjunction with FIGS. 1A to 1G or 2A to 2F. The carriers 1 are still provided in the composite in this case.

An application of optoelectronic semiconductor chips 2 is subsequently performed. In the exemplary embodiment of FIGS. 3A and 3B, these are light-emitting diode chips, in which a growth substrate 27, which is formed using sapphire, for example, remains in the semiconductor chip. Each optoelectronic semiconductor chip 2 has the growth substrate 27, an n-conductive region 24, a p-conductive region 25, a mirror 26, and through-contacts 28. The pn-junction 23 of the semiconductor chip 2 is arranged between the n-conductive region 24 and the p-conductive region 25. The through-contacts 28 extend, for example, from the second terminal point 22 into the n-conductive region, so that the second terminal region 22 forms the n-conductive terminal point of the semiconductor chip 2. The semiconductor chip 2 is connected via the first terminal region 21 on the p-side.

The semiconductor chips 2 are individually connected to the composite of carriers 1 such that the n-conductive terminal point of the second terminal region 22 is connected in an electrically conductive manner to the p-conductive second region B2 of the carrier. Accordingly, the p-conductive terminal point of the semiconductor chip 2, i.e., the first terminal region 21, is connected to the n-conductive first region B1 of the carrier. In this manner, the pn-junction 14 of the carrier and the pn-junction 23 of the semiconductor chip are connected in antiparallel to one another and the carrier 1 forms an ESD protection for the semiconductor chips 2.

Subsequently, isolation of the arrangement made of carrier 1 and optoelectronic semiconductor chip 2 to form individual optoelectronic semiconductor components can be performed, which each comprise precisely one optoelectronic semiconductor chip 2 in the exemplary embodiment of FIG. 3B. The optoelectronic semiconductor component is then connected on the n-side in the p-conductive second region B2 and connected on the p-side in the n-conductive first region B1. In this manner, the optoelectronic semiconductor chip 2 is electrically contacted and the carrier 1 forms an ESD protection.

The polarities in the semiconductor chip 2 and in the carrier 1 can also be selected in an exchanged manner in this case. That is to say, the base body 10 can be doped in an n-conductive manner, for example, and can be connected in an electrically conductive manner to the p-conductive region of the semiconductor chip 2.

A further exemplary embodiment of a method described here is explained in greater detail in conjunction with FIGS. 4A to 4E. In this exemplary embodiment, the optoelectronic semiconductor chips 2 are connected and connected in an electrically conductive manner not individually, but rather also in the wafer composite, to the carriers 1, which are provided in the composite.

The semiconductor chips 2 are firstly mechanically connected to one another via the growth substrate 27 and are mounted in the composite on the composite made of carriers 1. This is illustrated in conjunction with FIGS. 4A and 4B. In the next method step, FIG. 4C, the growth substrate 27, which can be formed using sapphire or silicon, for example, is removed by a laser removal process, an etching process, and/or mechanical ablation.

Subsequently, isolation into individual semiconductor chips 2 is performed, for example, by way of mesa etching, wherein the mesa etching can also be performed before the application of the semiconductor chips 2 to the carrier, i.e., still on the growth substrate 27. In this case, the mesa etching is performed from the side facing away from the growth substrate 27.

Furthermore, roughening of the outer surface of the semiconductor chips 2 can be performed, for example, by etching using KOH.

Finally, FIG. 4E, isolation into individual optoelectronic semiconductor components is performed.

Such an optoelectronic semiconductor component is illustrated once again in FIG. 5. The optoelectronic semiconductor component comprises the carrier 1 having the base body 10, which is formed, for example, from p-doped crystalline silicon. The recess 11, which is partially covered by the first electrically insulating material 15 on its lateral surfaces, is introduced into the base body 10. The remaining regions of the recess 11 are filled using the filler material 12, which has a smaller cross-sectional area A1 on the first main surface 10a and the second main surface 10b of the base body than the cross-sectional area A2 in the interior. The filler material 12 is, for example, n-doped polycrystalline silicon. The space charge zone 13 and the pn-junction 14 of the carrier are formed in the region of the direct contact between filler material 12 and base body 10.

The space charge zone 13 is created by diffusion of the n-dopant of the filler material into the p-doped material of the base body 10 during the tempering.

The base body 10 of the carrier is covered in a structured manner by the second electrically insulating material 16 on the first main surface 10a and the second main surface 10b. The second electrically insulating material 16 represents an electrical insulation between the electrically conductive material applied in the first region B1 and in the second region B2 of the carrier.

A semiconductor chip 2, which has an n-conductive region 24, a p-conductive region 25, and a pn-junction 23 inbetween is arranged on the upper side of the carrier 1 facing toward the first main surface 10a of the carrier 10.

Through-contacts 28 extend through the mirror 26, the p-conductive region 25, and the pn-junction 23 into the n-conductive region 24. The semiconductor chip 2 is connected to the p-conductive region of the carrier 1 on the n-side, i.e., at the second terminal region 22. On the lower side of the carrier 1 facing away from the semiconductor chip 2, the carrier can be electrically contacted on the n-side via the electrically conductive material 17 in the second region B2.

The semiconductor chip 2 is connected in a p-conductive and electrically conductive manner via the first terminal region 21 of the semiconductor chip 2 to the n-conductive first region B1, i.e., in the region of the filler material 12. In this first region B1, the carrier 1 is contacted on the p-side on its lower side via the electrically conductive material 17.

Overall, an optoelectronic semiconductor component results, which is producible particularly cost-effectively and is particularly space-saving, since an ESD protection is integrated via the carrier 1.

The invention is not restricted thereto by the description on the basis of the exemplary embodiments, but rather comprises every novel feature and every combination of features, which includes in particular every combination of features in the patent claims, even if these features or these combinations are not explicitly specified themselves in the claims or exemplary embodiments.

This patent application claims the priority of German patent application 102013105631.8, the content of the disclosure of which is hereby incorporated by reference.

### LIST OF REFERENCE SIGNS

1 carrier
10 base body
10a first main surface
10b second main surface
11 recess
12 filler material
12′ further filler material
121 metal
13 space charge zone
14 pn-junction of the carrier
15 first electrically insulating material
16 second electrically insulating material
17 electrically conductive material
18 doped region
19 transition
A1 first cross-sectional area
A2 second cross-sectional area
B1 first region of the carrier
B2 second region of the carrier
2 semiconductor chip
21 first terminal region
22 second terminal region
23 pn-junction of the semiconductor chip
24 n-conductive region
25 p-conductive region
26 mirror
27 growth substrate
28 through-contact

1. A carrier for an optoelectronic semiconductor chip comprising:
a base body, which comprises a first main surface and a second main surface
at least one recess, which is introduced into the base body and completely penetrates the base body from the first main surface to the second main surface; and
a filler material, which is introduced into the at least one recess,
wherein the base body is formed using silicon of a first conductivity type,
wherein the filler material is formed using polycrystalline silicon of a second conductivity type, the polarity of which differs in particular from the first conductivity type, and
wherein the base body and the filler material are in direct contact with one another at points.

2. The carrier according to claim 1, wherein a space charge zone is formed in the region of the direct contact.

3. The carrier according to claim 1, wherein a pn-junction is formed in the region of the direct contact.

4. The carrier according to claim 1, wherein a first electrically insulating material is arranged at points in the at least one recess between the filler material and the base body.

5. The carrier according to claim 1, wherein the filler material comprises a metal, wherein the polycrystalline silicon is arranged at least at points between the metal and the base body.

6. The carrier according to claim 1, wherein a second electrically insulating material, which completely encloses the opening of the recess on the first main surface and/or the second main surface, is applied to the first main surface and/or the second main surface.

7. The carrier according to claim 1, wherein a first cross-sectional area of the filler material on the first main surface and/or the second main surface is smaller than a second cross-sectional area (A2) inside the base body, which is arranged between the first main surface and/or the second main surface.

8. The carrier according to claim 1, wherein an electrically conductive material is applied in a structured manner to the first main surface and/or the second main surface, which electrically conductive material is in direct contact with the filler material in a first region (B1) of the carrier and is in direct contact with the base body in a second region (B2) of the carrier, wherein the electrically conductive material in the first region (B1) and the electrically conductive material in the second region (B2) are electrically insulated from one another by the second electrically insulating material.

9. The carrier according to claim 8, wherein a doped region, which comprises the first conductivity type, is arranged in the base body directly below the electrically conductive material in the second region (B2) on the first main surface and/or directly above the electrically conductive material in the second region (B2) on the second main surface.

10. An optoelectronic semiconductor component comprising:
a carrier according to claim 1; and
an optoelectronic semiconductor chip having a first electrical terminal region and a second electrical terminal region,
wherein the optoelectronic semiconductor chip is arranged on the side of the carrier facing toward the first main surface of the base body, and
wherein the optoelectronic semiconductor chip is connected in an electrically conductive manner to the carrier via the first electrical terminal region and the second electrical terminal region.

11. The optoelectronic semiconductor component according to claim 10, wherein the first electrical terminal region of the semiconductor chip is connected in an electrically conductive and mechanical manner to the electrically conductive material in the first region (B1) of the carrier and the second electrical terminal region of the semiconductor chip is connected in an electrically conductive and mechanical manner to the electrically conductive material in the second region (B2) of the carrier, and
wherein the first electrical terminal region and the second electrical terminal region are each connected to an electrically unlike region of the carrier.

12. The optoelectronic semiconductor component according to claim 10, wherein the optoelectronic semiconductor chip has a pn-junction, wherein the pn-junction of the carrier is connected in antiparallel to the pn-junction of the semiconductor chip.

13. The optoelectronic semiconductor component according to claim 10, wherein the carrier forms an ESD protective diode for the optoelectronic semiconductor chip.

14. A method for producing an optoelectronic semiconductor component comprising the following steps:
producing a plurality of carriers according to claim 1 in a composite;
applying and connecting in an electrically conductive manner a plurality of optoelectronic semiconductor chips to the plurality of carriers; and
isolating the arrangement made of carriers and optoelectronic semiconductor chips to form individual optoelectronic semiconductor components, wherein each optoelectronic semiconductor component comprises at least one optoelectronic semiconductor chip.
